(19) United States
(12) Patent Application Publication
(10) Pub. No.: US 2009/0195286 A1
(43) Pub. Date: Aug. 6, 2009

(54) PHASE SHIFTING USING ASYMMETRIC INTERPOLATOR WEIGHTS

(76) Inventor: Sergey Vladimirovich Rylov, White Plains, NY (US)

Correspondence Address: IBM CORP (YA);C/O YEE & ASSOCIATES PC, P.O. BOX 802333, DALLAS, TX, 75380, US

(21) Appl. No.: 12/024,043

(22) Filed: Jan. 31, 2008

(51) Int. Cl. H03H 11/16

(52) U.S. Cl. 327/237

(57) ABSTRACT

Illustrative embodiments provide an apparatus for phase shifting to produce uniform phase steps in a predictable manner to improve the linearity of conversion. The apparatus comprises a phase selector for selecting two or more phases to create selected phases and a phase interpolator capable of receiving the selected phases. The apparatus further comprises a set of digital to analog converter cells connected to the phase interpolator, wherein interpolator weight distribution among the set of digital to analog converter cells is non-linear, and a thermometer code in communication with the set of digital to analog converter cells, wherein the thermometer code adjusts output of the set of digital to analog converter cells to phase shift the selected phases.

### BACKGROUND

1. Field of the Invention

The present application relates generally to an improved data processing system and in particular to a computer implemented method and an apparatus for phase shifting using asymmetric interpolator weights.

2. Description of the Related Art

In the field of high-precision phase shifting of high-speed, multi-GHz clock signals used in modern computer and communications circuits as found in multi-Gigabit serial data links, the phase shifts, also known as phase rotation, can typically travel continuously around the phase circle and are controlled with digital code. Such digital-to-phase converters with unlimited phase range are known as phase rotators.

Phase rotators are commonly built using phase selection and interpolation architecture. In this architecture, two or more, clock phases are selected from a larger set of clock phases distributed uniformly on a phase circle. For example, two phases can be selected from a set of four quadrature phases with phase angles of 0, 90,180, and 270 degrees. These selected phases are applied to a phase interpolator circuit that mixes the phases using predetermined weights that are digitally controlled.

The values of individual phase delays produced by a phase rotator are typically affected by these interpolator weights; however the weight-to-phase conversion is usually non-linear. This means that uniform changes in the weight factors do not necessarily result in uniform phase steps.

A requirement therefore exists to improve the linearity of conversion to produce uniform phase steps in a predictable manner.

### SUMMARY

Illustrative embodiments provide an apparatus for phase shifting. In an illustrative embodiment, the apparatus comprises a phase selector for selecting two or more phases to create selected phases and a phase interpolator capable of receiving the selected phases. The apparatus further comprises a set of digital to analog converter cells connected to the phase interpolator, wherein interpolator weight distribution among the set of digital to analog converter cells is non-linear, and a thermometer code in communication with the set of digital to analog converter cells, wherein the thermometer code adjusts output of the set of digital to analog converter cells to phase shift the selected phases.

### BRIEF DESCRIPTION OF THE DRAWINGS

The novel features believed characteristic of the illustrative embodiments are set forth in the appended claims. The illustrative embodiments themselves, however, as well as a preferred mode of use, further objectives and advantages thereof, will best be understood by reference to the following detailed description of the illustrative embodiments when read in conjunction with the accompanying drawings, wherein:

FIG. 1 is a block diagram of a data processing system, in accordance with a preferred embodiment of the present invention;

FIG. 2 is a block diagram of a phase rotator, in accordance with a preferred embodiment of the present invention;

FIG. 3 is a block diagram of rotator phase positions and quadrant transitions, in accordance with a preferred embodiment of the present invention; and

FIG. 4 is a tabular representation of values associated with the rotator phase positions of FIG. 3, in accordance with a preferred embodiment of the present invention.

### DETAILED DESCRIPTION OF THE PREFERRED EMBODIMENT

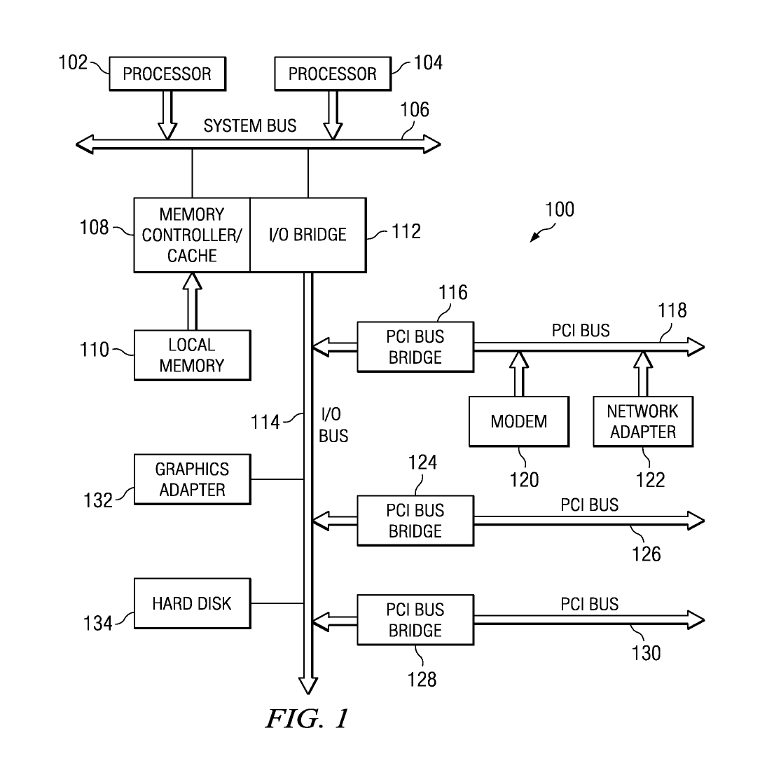

Referring to FIG. 1, a block diagram of a data processing system, is depicted in accordance with a preferred embodiment of the present invention. Data processing system 100 may be a symmetric multiprocessor (SMP) system including a plurality of processors 102 and 104 connected to system bus 106. Alternatively, a single processor system may be employed. Memory controller/cache 108 also connects to system bus 106, which provides an interface to local memory 110. I/O bridge 112 is connected to system bus 106 and provides an interface to I/O bus 114. Memory controller/cache 108 and I/O bridge 112 may be integrated as depicted.

Peripheral component interconnect (PCI) bus bridge 116 connects to I/O bus 114 providing an interface to PCI local bus 118. A number of modems may connect to PCI local bus 118. Typical PCI bus implementations will support four PCI expansion slots or add-in connectors. Communications links to other systems may be provided through modem 120 and network adapter 122 connected to PCI local bus 118 through add-in boards.

Additional PCI bus bridges 124 and 128 provide interfaces for additional PCI local buses 126 and 130, from which additional modems or network adapters may be supported. In this manner, data processing system 100 allows connections to multiple network computers. A memory-mapped graphics adapter 132 and hard disk 134 may also be connected to I/O bus 114 as depicted, either directly or indirectly.

Those of ordinary skill in the art will appreciate that the hardware depicted in FIG. 1 may vary. For example, other peripheral devices, such as optical disk drives and the like, also may be used in addition to or in place of the hardware depicted. The depicted example is not meant to imply architectural limitations with respect to the present invention.

The data processing system depicted in FIG. 1 may be, for example, an IBM® e-Server™ pSeries™ system, a product of International Business Machines Corporation in Armonk, N.Y., running the Advanced Interactive Executive (AIX®) operating system or LINUX™ operating system.

Timing components such as clocks may be implemented within the components of data processing system 100. For example, processor 102 and processor 104 may have a serial link between them using a phase rotator, as may system bus 106, PCI Bus Bridge 116 and memory controller/cache 108. In an alternative embodiment, on more clocks may be used to commonly provide timing for the previously described components. Typically as execution speed increases, the requirement for unique timing components increases resulting in each component having a timing component. When multiple clocks are present, one clock may be referred to as the system clock or reference clock. This clock may provide a reference for other clocks to use when synchronizing time is required. Pairs of clocks may also be used together to provide differential input to timing services.

Illustrative embodiments provide a capability for high precision phase shifting using differential clock inputs from components, such as processor 102 and processor 104 to be performed. Digital code applied to a phase rotator component modifies phase shifting of the inputs. The phase rotator may be implemented as a portion of system bus 106 or PCI Bus Bridge 116. The phase rotator interpolates the selected, by mixing the selected phases using a set of interpolator weights. The interpolator weights are digitally controlled in these examples. The interpolator weights are defined in an asymmetric manner to provide typically more uniform phase steps than previously obtained.

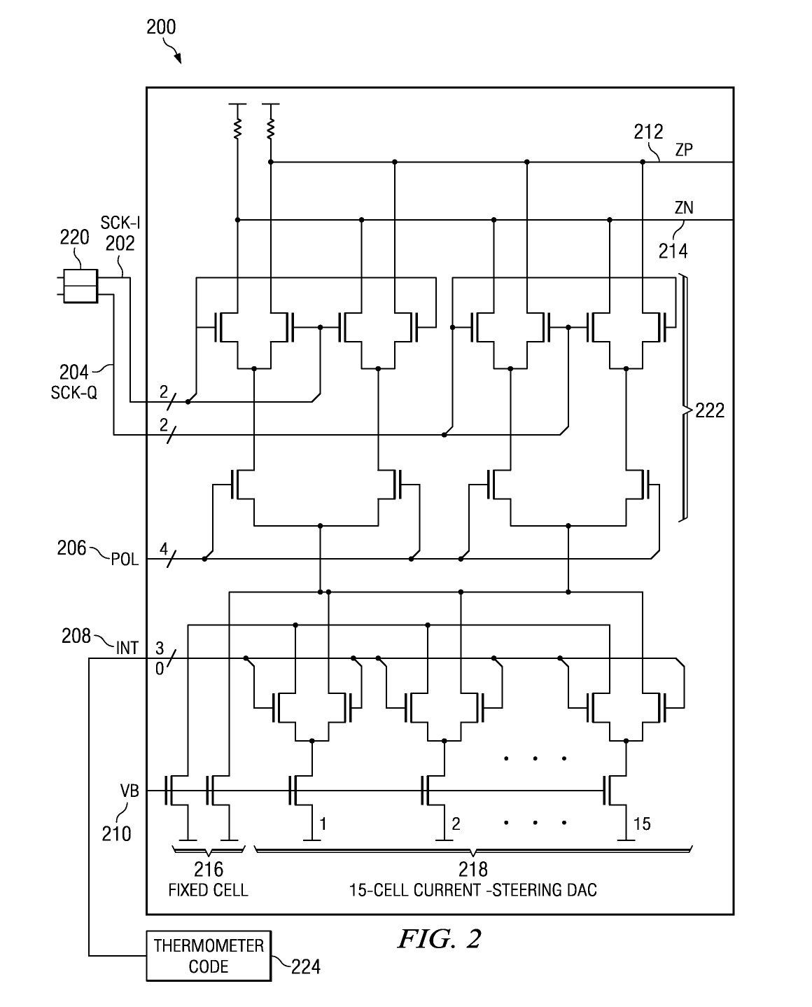

With reference to FIG. 2, a block diagram of a phase rotator, in accordance with a preferred embodiment of the present invention is shown. In this example, phase rotator 200 is comprised of a number of components including transistors and resistors as is known in the art and these will not be further described.

System timing components provide selected inputs via inputs 202 and 204 to phase rotator 200. For example, clock data may be provided for a system clock I (SCK-I) and a system clock Q (SCK-Q). Other clock inputs may be used as well such as those associated with serial links embedded in the system components of FIG. 1. Slew buffers 220 are used to adjust and maintain the slew rate of input clock phases to ensure overlap of the two clock edges being interpolated. A respective slew buffer processes each of the selected inputs. Polarity 206 controls polarity adjustments to input of the selected phases. Input 210 applies current while input 208 applies thermometer code 224 to a set of digital to analog converters (DAC) 218. The set of digital to analog converters contains one or more digital to analog converters. Fixed cell 216 is used to provide a constant pre-determined current in addition to the current supplied by current input 210. Fixed cell 216 ensures current is always applied to the phase rotator phases to reduce possible delays due to start and stop current fluctuations. Fixed cell 216 may be a set of cells, wherein the set contains one or more cells. Configurable control over the set of digital to analog converter current is provided through input 208. The set of digital to analog converters may be a multiple of sets. Each set is comprised of one or more converter cells. In this example cells 1 to 15 are provided.

The current is applied, by a timing component through a set of digital to analog converters 218. The set of digital to analog converters adjusts the current applied to elements, attached to input 202 and input 204 and output 212 and output 214, forming phase interpolator 222 of phase rotator 200. The results of modifying the phases, received as selected input, are then provided as output 212 and 214.

Illustrative embodiments provide a capability of improving linearity of phase rotator architectures that use interpolators with a high level of asymmetry of interpolator weight-to-phase conversion. Such asymmetry is usually observed in rotators that interpolate between two clock phases with relatively large phase separation, for example, 90 degrees, and operate close to the bandwidth limit of a given technology. Use of such phase rotator architectures with relatively high intrinsic non-linearity is typically justified by the compactness and lower power requirements when compared to other means that are intrinsically more linear but are also more complex and consume more power.

Improvements in phase rotator linearity may be obtained while retaining power and area advantages of simple phase rotator architectures by pre-distorting the interpolator weights to cancel out the non-linearity. Addressing asymmetry using a pre-distortion approach typically requires an effective encoding, the thermometer code, to seamlessly connect neighboring interpolation regions separated by a phase switching boundary.

Typical two-phase interpolators use a weight-steering approach for directing current, where the sum of weights assigned to the both phases stays constant as in 100%, while only the ratio of the weights changes. This is commonly achieved by using a digital to analog converter composed of “n” topologically identical 1-bit digital to analog converter cells that assign all their weight either to phase 1 or phase 2, depending on a control bit. An n-section digital to analog converter yields “n+1” different interpolator states derived from “n” cells driving phase 1, 0 cells driving phase 2 to 0 cells driving phase 1, and “n” cell driving phase 2.

The code controlling the digital to analog converter is essentially a thermometer code, since only one bit of the code changes at every rotator step, and every bit changes only once while the rotator is stepping over the entire interpolation range from state (n,0) to state (0,n). Typically such thermometer coding in phase rotator interpolators provides predictable operation, but also creates a one-to-one mapping between individual interpolator steps and digital to analog converter cells. The unique mapping provides a capability to modify each step individually for optimum linearity by adjusting the respective digital to analog converter interpolator weights.

Typically, to achieve effective operation of a phase rotator with an asymmetric interpolator across the entire phase circle, the digital to analog converter cells must be managed, or steered, in a proper order, or sequence, when crossing the phase switching boundary.

For example, assume that the rotator steps continuously in one direction of increasing delay, starting with phase 1 and initially steps toward phase 2, which lags phase 1, via interpolating between the phases and progressively steering the digital to analog converter cells 1, 2, . . . n from phase 1 to phase 2. Upon reaching phase 2, the rotator substitutes phase 1 with phase 3, which both have vanishing weight at that moment, and proceeds to steer the digital to analog converter cells back from phase 2 to phase 3. Phase 3 is being applied to the same interpolator input as phase 1 before the phase switch. In respect to phase 2, phase 3 is now a lagging phase, while phase 1 was a leading phase. This means that different digital to analog converter sections should be used on the two sides of the switching boundary. The proper sequence of switching is not to retrace the prior sequence (1, 2, . . . n) in reverse order (n, n−1, . . . , 2, 1), but instead the process is simply repeating the sequence again as in (1, 2, . . . n).

For example, in current mode logic interpolators a symmetric digital to analog converter causes reduced phase steps towards the leading phase and increased steps toward the lagging phase. In this example, the appropriate digital to analog converter pre-distortion would be to use larger digital to analog converter sections for stepping towards a leading phase and smaller digital to analog converter sections for stepping towards the lagging phase.

In an illustrative embodiment, phase rotator 200 is a 16-state interpolator operating on a set of four quadrature phases forming two differential quadrature clock phases, I and Q. In operation, phase rotator 200 selects polarity of the phases, the quadrant selection, and then interpolates between the phases to generate 16 equidistant phase positions within each quadrant for a total of 64 possible phase positions on a 360 degree circle. The interpolator circuit uses a current-steering digital to analog converter which supplies tail currents to the non-field effect transistor differential pairs processing clock phases I and Q and having a common resistive load.

Phase rotator 200 may be preceded by a pair of slew-rate-control buffers or slew buffers 220. In order to achieve high-precision interpolation, the slew rate of input clock phases is typically managed sufficiently low to ensure overlap of the two clock edges being interpolated.

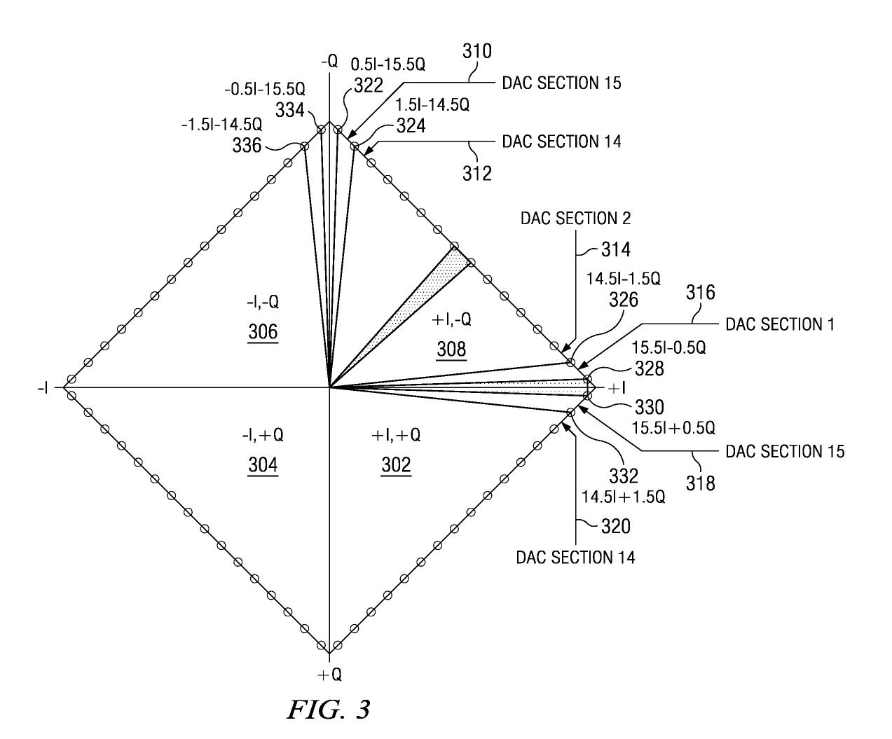

With reference to FIG. 3, a block diagram of rotator phase positions and quadrant transitions, in accordance with a preferred embodiment of the present invention is shown.

Rotator phase positions and quadrant transitions 300 shows a 64-point phase constellation in a diamond shape. The diamond is composed of quadrants 302, 304, 306 and 308, reflecting a constant total interpolator tail current. Each of the two tail currents of the interpolator can receive from 0 to 15 current units from the current steering digital to analog converter cells 218 and an extra half current unit from the fixed or non-switched, cell 216 both of FIG. 2. Each quadrant indicates a phase of each clock phase in the combination of the clock phases.

For example, when moving from quadrant 304 to quadrant 306, paired clock phases “−I, −Q” changes to “−I+Q.” The left hemisphere indicates clock phase “I” will be “−I,” while the right hemisphere indicates clock phase “I” will be “+I.” In a similar manner upper and lower hemispheres indicate the setting for clock phase “Q.”

This form of configuration produces 16 different interpolation ratios of 0.5:15.5, 1.5:14.5, through 15.5:0.5, wherein the actual ratios depend on the sizing of individual digital to analog converter cells, such as 310, 312, 314, 316, 318 and 320. The ratios describe the current allocations to clock phases I and Q, such as those indicated by ratios 322, 324, 326, 328, 330, 332, 334, and 336. For example, using ratio 322 of 0.5I+15.5Q and ratio 334 of −0.5I+15.5Q, the phase change for clock phase I may be seen as the rotation traverses the tip of the diamond shape. The ratio remains the same while the polarity changed indicating a flip in polarity as the rotation moves from one digital to analog conversion section to another.

Use of fixed cell 216 in FIG. 2 avoids applying zero tail current to the interpolator branches thus improving rotator settling time. In addition, when the rotator steps across the quadrant boundary the interpolation ratio stays constant, so only polarity of one of the input phases needs to be switched. This is achieved by maintaining a half-rotator step separation between the diamond vertices and the nearest rotator phase states by optimizing the size of the fixed digital to analog converter cell.

The current steering digital to analog converter cells are not uniform. The relative sizing is optimized for rotator linearity, with the largest cells being switched near the quadrant boundaries. Generally digital to analog converter section non-uniformity comes from a non-circular, such as diamond, shape of the phase constellation. Uniform digital to analog converter sections would produce uniform distribution of phase states on the diamond sides, but non-uniform distribution of phase angles. Simple geometry indicates angles near the middle of the quadrant formally exceed those near quadrant boundaries by a factor of 2, but typical non-uniformity is much weaker and often substantially asymmetric. Asymmetry manifests, for example, in that equal digital to analog converter section 1 316 and digital to analog converter section 15 310 produce unequal phase steps, which is contrary to what a linear mixing theory would suggest.

Correction of this asymmetry, therefore typically involves, the distribution of digital to analog converter interpolator weights 1 through 15 in a non-symmetric manner, and use of a thermometer code that supports asymmetry, as described in the following section.

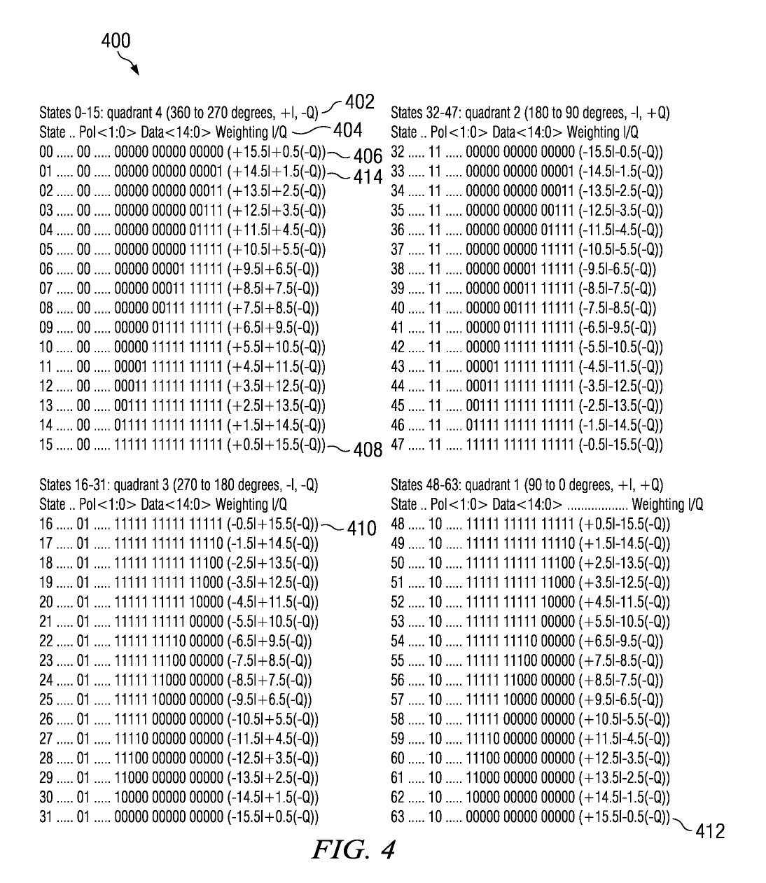

With reference to FIG. 4, a tabular representation of values associated with the rotator phase positions of FIG. 3, in accordance with a preferred embodiment of the present invention is shown. Lines 400 describe a set of sixty four possible rotator states numbered from 0 to 63 and the corresponding values of a 17-bit phase rotator input vector. The phase rotator vector comprises two polarity bits of POL_1, POL_0, controlling “Q” and “I” input clock phases respectively, and 15 thermometer code bits, Data<14:0>, controlling digital to analog converter cells from 15 to 1 respectively.

Header 402 indicates the following information, from left to right: state range, quadrant number, degree range covered and clock phase of each clock. In this case, state range is between 0 and 15; the quadrant is 4; the degree range is between 360 to 270; and the clock phases are “+I” and “−Q.” Header 404 indicates the current state, the polarity setting, the data setting, and the weighting assigned to each of the clock phases “I” and “Q.”

The rotator states may be uniformly distributed about a 360 degree phase circle with a nominal separation of one LSB equal to 360/64 or 5.625 degrees, creating a equal angle of separation, and an offset of one half LSB in respect to the zero phase position, for example, clock phase I. Positive rotation direction corresponds to progressively decrementing the rotator output phase, manifesting in progressively decreasing rotator delay and associated finite positive frequency offset.

Row 406 describes rotator state #0, encoded with 15+2 zeros, defined as assigning a maximum positive weight, shown as +15.5 units, to clock phase “I”, marked as phase “C0”, and a minimum positive weight, as +0.5 units, to phase “−Q” or “C270.” Accordingly, state #0 is labeled as “+15.5I+0.5(−Q)”. The reason for using phase “−Q” instead of “Q” is to preserve the prior definition of positive rotator direction which has reducing delay.

Rotator state #1, row 414, is obtained by steering one unit of digital to analog converter current from phase “I” to phase “−Q” and is labeled as “+14.5I+1.5(−Q).” This change is achieved by flipping the thermometer code bit #0 that controls digital to analog converter section #1. A step in opposite direction, traversing from state #0, row 406 to state #63, row 412, is achieved by keeping the digital to analog converter weighting intact, at 15.5/0.5, but flipping the polarity bit #1 that controls phase “−Q”, so state #63 is labeled “+15.5I-0.5(−Q).”

A similar quadrant change may be seen between row 408 and row 410 reflecting movement between states 15 and 16. The polarity changes from a value of 00 to a value of 01 while the data values remain the same. The weighting of 0.5/15.5 remains intact while the polarity changed.

Mapping of 64 rotator states to thermometer code bits in the phase rotator of this illustrative embodiment differs from previous phase rotators to enable support of asymmetric digital to analog converters. Specifically, digital to analog converters cell “i” controlled by thermometer code bit “i−1” serves transitions between rotator states “i−1 modulo 16” and state “i modulo 16.” For example, current steering by digital to analog converters cell #1 serves transitions between rotator states 0 and 1, between states 16 and 17, between states 32 and 33, and between states 48 to 49.

When compared to previous mapping techniques, bits of the thermometer code of an illustrative embodiment are now transposed in quadrants 2 and 4, so regions of “1” and “0” in the table of FIG. 4 now have a shape similar to a diagonal ribbon, representing a cyclically rotating pattern. Prior implementations typically produced a pattern more like triangles. The thermometer code, of this example, may be referred to as rotating thermometer code. The thermometer code provides a 50% duty cycle of all its bits when the phase rotator continuously steps in one direction. This means all bits are changed only once and there is an equal balance of “0” and “1” values.

Illustrative embodiments provide a capability for high precision phase shifting using selected phase inputs, from components such as processor 102 and processor 104 of FIG. 1, to improve performance of serial links. The phase shifting of the selected phase input is modified through the use of digital code applied to a phase rotator. A phase rotator may be implemented where a serial link may exist as a portion of system bus 106, PCI Bus Bridge 116 and memory controller/cache 108 of FIG. 1. The phases selected are then interpolated, in the phase rotator, by mixing the input phases using interpolator weights that are digitally controlled using a thermometer code. The interpolator weights are defined in an asymmetric manner to provide typically more uniform phase steps than previously obtained.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The description of the illustrative embodiments have been presented for purposes of illustration and description, and is not intended to be exhaustive or limited to the illustrative embodiments in the form disclosed. Many modifications and variations will be apparent to those of ordinary skill in the art. The embodiment was chosen and described in order to best explain the principles of the illustrative embodiments, the practical application, and to enable others of ordinary skill in the art to understand the illustrative embodiments for various embodiments with various modifications as are suited to the particular use contemplated.

What is claimed is:

1. An apparatus for phase shifting, the apparatus comprising;
a phase selector for selecting two or more phases to create selected phases;
a phase interpolator capable of receiving the selected phases;
a set of digital to analog converter cells connected to the phase interpolator, wherein interpolator weight distribution among the set of digital to analog converter cells is non-linear and asymmetric; and
a thermometer code in communication with the set of digital to analog converter cells, wherein the thermometer code adjusts output of the set of digital to analog converter cells to phase shift the selected phases.

2. The apparatus for phase shifting of claim 1, wherein the set of digital to analog converter cells comprises:
multiple sets of digital to analog converter cells.

3. The apparatus for phase shifting of claim 1, wherein each cell within a set is sequentially numbered and mapped one for one within a range to steps of the phase interpolator, a first cell forming a first step and a last cell forming step within the range.

4. The apparatus for phase shifting of claim 1, wherein the set of digital to analog converter cells further comprises a fixed cell providing a half unit of weight to each of the selected phases, wherein the fixed cell always applies a non-zero weight to the selected phases.

5. The apparatus for phase shifting of claim 3, wherein the phase selector traverses a boundary between ranges by switching a selected phase going into input of the phase interpolator that receives a minimum weight, forming a boundary step and the boundary separating preceded by switching the last cell of digital to analog converter cells and followed by switching the first cell of digital to analog converter cells.

6. The apparatus for phase shifting of claim 1, wherein the selected phases are processed by a slew buffer.

7. The apparatus for phase shifting of claim 1, wherein the thermometer code controlling each cell of the digital to analog converter cell wherein is assigned one bit of the thermometer code.

8. The apparatus for phase shifting of claim 1, wherein the phase interpolator further comprising rotator states uniformly distributed about a circle to create an equal angle of separation of the rotator states forming a phase rotator having unlimited phase range.

9. The apparatus for phase shifting of claim 1, wherein the implementation uses current mode logic (CML).
